(19) United States
(12) Patent Application Publication
(10) Pub. No.: US 2025/0318113 A1
(43) Pub. Date: Oct. 9, 2025

(54) MICROELECTRONIC DEVICES AND RELATED METHODS AND MEMORY DEVICES

(71) Applicant: Micron Technology, Inc., Boise, ID (US)

(72) Inventor: Pengyuan Zheng, Boise, ID (US)

(21) Appl. No.: 19/075,612

(22) Filed: Mar. 10, 2025

Related U.S. Application Data
(60) Provisional application No. 63/631,928, filed on Apr. 9, 2024.

(51) Int. Cl. H10B 41/20; H10B 41/35; H10B 80/00; H10D 64/01; H10D 64/20; H10D 64/27; H10D 64/66; H10D 64/68; H10D 88/00

(52) U.S. Cl. CPC H10B 41/20; H10B 41/35; H10B 80/00; H10D 64/01; H10D 64/205; H10D 64/27; H10D 64/665; H10D 64/691; H10D 64/693; H10D 88/01

(57) ABSTRACT

A microelectronic device includes a conductive structure and a conductive contact structure on the conductive structure. The conductive contact structure on the conductive structure includes a conductive pad structure, a metal silicide material over the conductive pad structure, and a conductive fill material surrounded by the metal silicide material. The metal silicide material physically contacts and substantially covers sidewalls and a bottom surface of the conductive fill material. Related methods and memory devices are also described.

### CROSS-REFERENCE TO RELATED APPLICATIONS

This application claims the benefit under 35 U.S.C. § 119 (e) of U.S. Provisional patent application Ser. No. 63/631,928, filed Apr. 9, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices, and to related microelectronic devices, memory devices, and electronic systems.

### BACKGROUND

A continuing goal of the microelectronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in tiers of conductive structures (e.g., word lines) and dielectric materials at each junction of the vertical memory strings and the conductive structures. Such a configuration permits a greater number of switching devices (e.g., transistors) to be located in a unit of die area (i.e., length and width of active surface consumed) by building the array upwards (e.g., longitudinally, vertically) on a die, as compared to structures with conventional planar (e.g., two-dimensional) arrangements of transistors.

Conventional vertical memory arrays include electrical connections between the conductive structures and access lines (e.g., word lines) so that memory cells in the vertical memory array can be uniquely selected for writing, reading, or erasing operations. One method of forming such an electrical connection includes forming so-called “staircase” (or “stair step”) structures at edges (e.g., horizontal ends) of the tiers of conductive structures. A staircase structure includes individual “steps” defining contact regions of the conductive structures upon which conductive contact structures can be positioned to provide electrical access to the conductive structures. So-called “stadium” structures may be formed to include opposing staircase structures.

The conductive contact structures can be found in different regions (such as the memory array region or the staircase region) within the vertical memory array and may serve different functions. For example, the conductive contact structures in the memory array region may serve as the vertical memory strings extending through the tier of conductive structures or as support structures. The conductive contact structures in the staircase region may serve to provide electrical access to the steps or may extend through the area between stadium structures or through the staircase structures themselves to electrically connect routing structures. The contact structures may include a dielectric material liner and a contact core that further includes a metal silicide liner and a metallic fill.

As vertical memory array technology has advanced, additional memory density has been provided by forming vertical memory arrays to include additional tiers of conductive structures, and, hence, additional staircase structures and/or additional steps in individual staircase structures associated therewith. However, as feature packing densities have increased and margins for formation errors have decreased, conventional configurations have resulted in undesirable defects (e.g., pillar bending, block bending, and slit cracking) that can diminish desired memory device performance, reliability, and durability.

### BRIEF DESCRIPTION OF THE DRAWINGS

FIGS. 1A through 1I are simplified, partial vertical cross-sectional views illustrating a method of forming a microelectronic device structure, in accordance with embodiments of the disclosure;

FIG. 2 is a simplified, partial vertical cross-sectional view of a microelectronic device, in accordance with embodiments of the disclosure; and

FIG. 3 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes a microelectronic device exhibiting, but not limited to, memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the singular forms following “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 104 S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}AS_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials. In addition, a “semiconductor structure” or a “semiconductor structure” means and includes a structure formed of and including semiconductor material.

Formulae including one or more of “x,” “y,” and “z” herein (e.g., SiOₓ, AlOₓ, HfOₓ, NbOₓ, TiOₓ, SiN_{y}, SiOₓ N_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

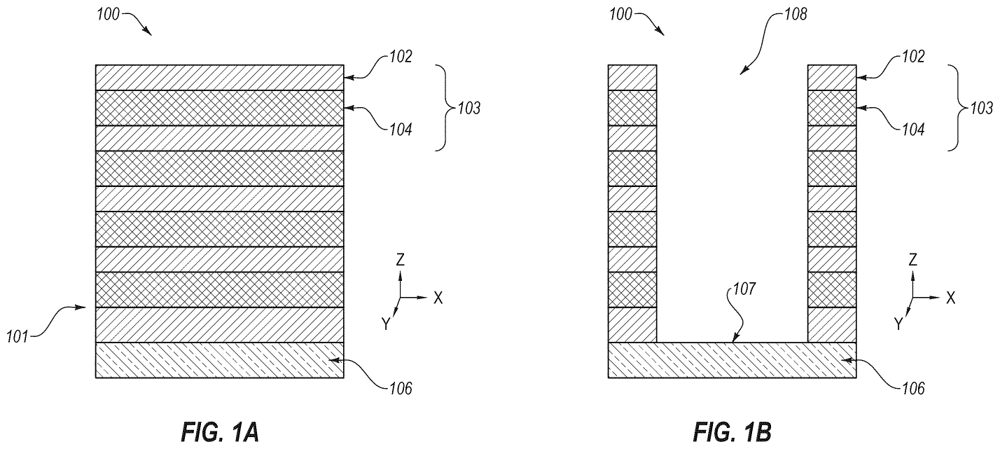

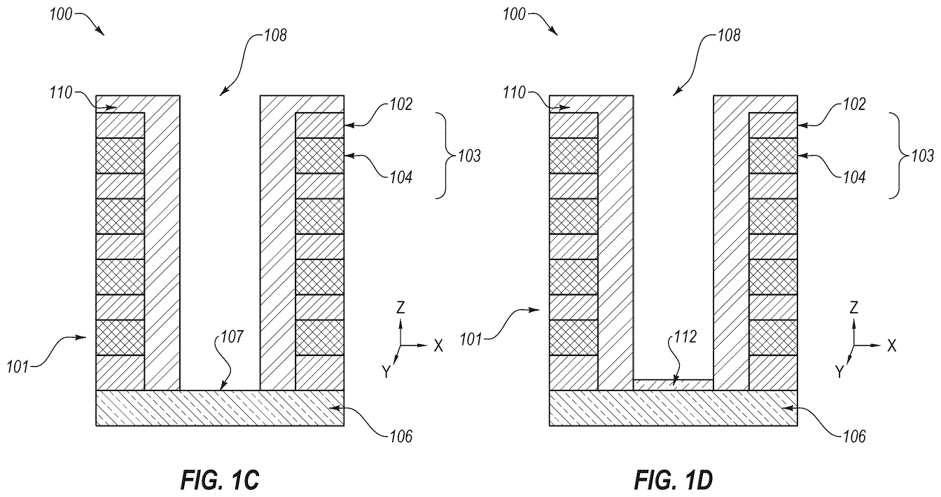

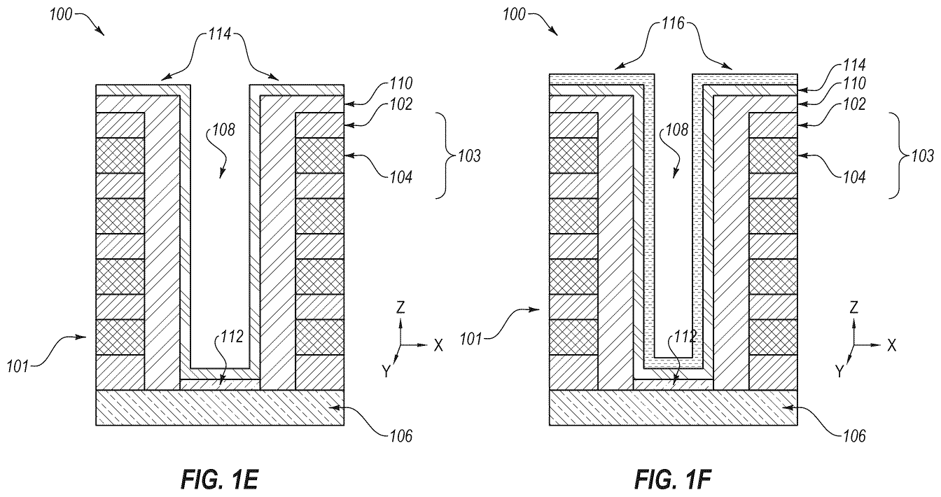

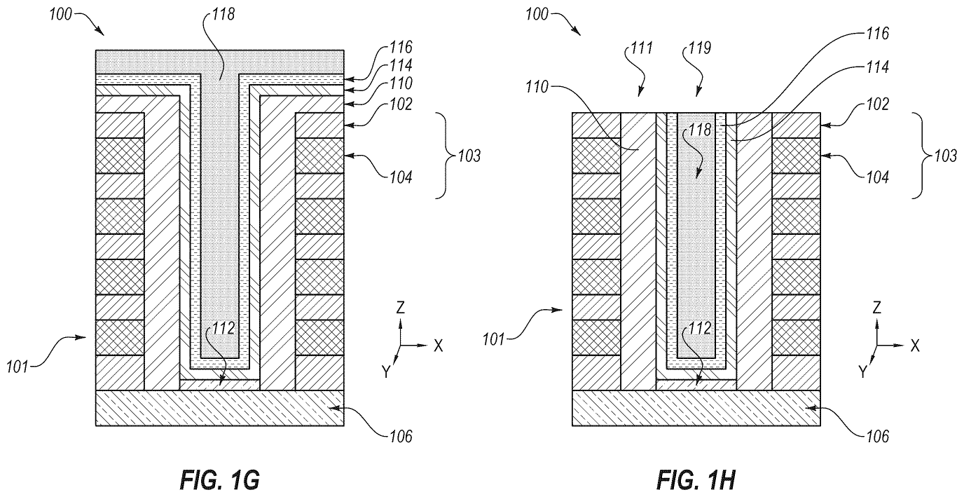

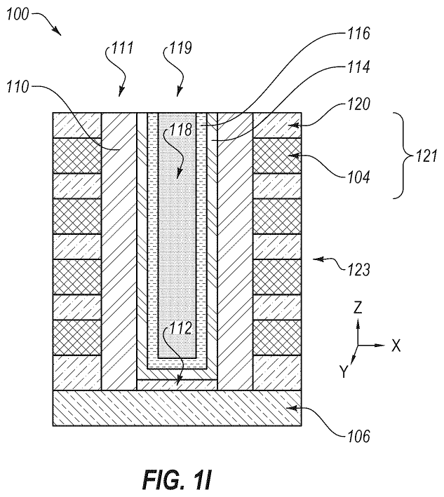

FIGS. 1A through II are simplified, partial vertical cross-sectional views illustrating embodiments of a method of forming a microelectronic device (e.g., a memory device, such as a 3D NAND Flash memory device). With the description provided below, it will be readily apparent to one of ordinary skill in the art that the methods and structures described herein may be used to form various devices and electronic systems.

Referring to FIG. 1A, the microelectronic device structure 100 may be formed to include a preliminary stack structure 101 on or over a base structure 106. The base structure 106 may be formed of and include conductive material. For example, the base structure 106 may be formed of and include one or more of at least one metal (e.g., one or more of W, Ti, Mo, Nb, V, Hf, Ta, Cr, Zr, Fc, Ru, Os, Co, Rh, Ir, Ni, Pd, Pt, Cu, Ag, Au, and Al), at least one alloy (e.g., one or more of a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, and a stainless steel), at least one conductive metal-containing material (e.g., one or more of a conductive metal nitride, a conductive metal silicide, a conductive metal carbide, and a conductive metal oxide), and at least one conductively doped semiconductor material (e.g., one or more of conductively doped Si, conductively doped Ge, and conductively doped SiGe). In some embodiments, at least an upper portion of the base structure 106 is formed of and includes metal silicide material, such as WSiₓ. The base structure 106 may, for example, be employed for one or more routing structures of a microelectronic device formed through the methods of the disclosure. In some embodiments, at least an upper portion of the base structure 106 is configured for use as a source structure (e.g., a source plate) for a microelectronic device.

The preliminary stack structure 101 includes a vertically alternating (e.g., in the Z-direction) sequence of sacrificial material 102 and insulative material 104 arranged in tiers 103. Each of the tiers 103 of the preliminary stack structure 101 may include at least one (1) level of the sacrificial material 102 vertically neighboring at least one (1) level of the insulative material 104. The preliminary stack structure 101 may include a desired quantity of the tiers 103. For example, the preliminary stack structure 101 may include greater than or equal to ten (10) of the tiers 103, greater than or equal to twenty-five (25) of the tiers 103, greater than or equal to fifty (50) of the tiers 103, greater than or equal to one hundred (100) of the tiers 103, greater than or equal to one hundred and fifty (150) of the tiers 103, or greater than or equal to two hundred (200) of the tiers 103 of the sacrificial material 102 and the insulative material 104.

The insulative material 104 of the tiers 103 of the preliminary stack structure 101 may be formed of and include at least one dielectric material. In some embodiments, the insulative material 104 of respective tiers 103 of the preliminary stack structure 101 is formed of and includes dielectric oxide material (e.g., SiOₓ, such as SiO₂).

The sacrificial material 102 of the tiers 103 of the preliminary stack structure 101 may be formed of and include at least one material that is selectively etchable relative to at least the insulative material 104 of the tiers 103 of the preliminary stack structure 101. As used herein, a material is “selectively etchable” relative to another material if the material exhibits an etch rate that is at least about five (5) times (5×) greater than the etch rate of another material, such as about ten (10) times (10×) greater, about twenty (20) times (20×) greater, or about forty (40) times (40×) greater. A material composition of the sacrificial material 102 is different than a material composition of the insulative material 104. In some embodiments, the sacrificial material 102 of respective tiers 103 of the preliminary stack structure 101 is formed of and includes dielectric nitride material (e.g., SiN_{y}, such as Si₃N₄).

Referring next to FIG. 1B, at least one opening 108 (e.g., trench, via, aperture) may be formed to extend through the preliminary stack structure 101 and to the base structure 106. The opening 108 may partially expose an upper surface 107 of the base structure 106. The upper surface 107 of the base structure 106 may define a lower vertical boundary (e.g., floor, bottom) of the opening 108, and side surfaces (e.g., sidewalls) of the tiers 103 of the preliminary stack structure 101 may at least partially define the horizontal boundaries (e.g., sides) of the opening 108.

The opening 108 may be formed to exhibit a desired geometric configuration (e.g., a desired shape and desired dimensions). The geometric configuration of the opening 108 may at least partially depend on the geometric configurations of additional structures (e.g., liner structures, additional conductive structures) to be formed within the opening 108, as described in further detail below. In some embodiments, the opening 108 has a substantially circular horizontal cross-sectional shape.

Referring next to FIG. 1C, a dielectric liner material 110 may be formed on or over surfaces of the microelectronic device structure 100 inside and outside of the opening 108. The dielectric liner material 110 may partially (e.g., less than completely) fill the opening 108. The dielectric liner material 110 may partially cover portions of upper surface 107 of the base structure 106 exposed within the opening 108, and may substantially cover side surfaces of the preliminary stack structure 101 partially defining the opening 108 and an uppermost surface of the preliminary stack structure 101.

The dielectric liner material 110 may be formed of and include at least one insulative material. In some embodiments, the dielectric liner material 110 is formed of and includes dielectric oxide material (e.g., SiOₓ, such as SiO₂). The dielectric liner material 110 may be substantially homogeneous or may be heterogeneous.

A thickness of the dielectric liner material 110 may at least partially depend on the dimensions (e.g., horizontal width, vertical height) of the opening 108 and on dimensions of additional materials and structures to be formed within a remainder of the opening 108. By way of non-limiting example, the thickness of the dielectric liner material 110 may be within a range of from about two (2) nm to about 10 nm, such as from about 2 nm to about 8 nm, or from about 2 nm to about 5 nm. In some embodiments, the dielectric liner material 110 is formed to exhibit a thickness within a range of from about 2 nm to about 4 nm.

The dielectric liner material 110 may be formed using one or more conventional processes (e.g., conventional material deposition processes, such as conventional conformal material deposition processes) and conventional process equipment, which are not described in detail herein. By way of non-limiting example, an insulative material may be conformally deposited (e.g., through one or more of an ALD process and a conformal CVD process) at least on the surface of the base structure 106 and the preliminary stack structure 101 inside and outside of the opening 108. Thereafter, a portion of the insulative material at the bottom of the opening 108 may be removed to form the dielectric liner material 110. The removal of the portion of the insulative material at the bottom of the opening 108 may be achieved using anisotropic etching (e.g., anisotropic dry etching, such as one or more of RIE, deep RIE, plasma etching, reactive ion beam etching, and chemically assisted ion beam etching).

Referring next to FIG. 1D, a conductive pad 112 may be formed at the bottom of the opening 108. The conductive pad 112 may partially (e.g., less than completely) fill a remainder of the opening 108. The conductive pad 112 may substantially cover the portion of the upper surface 107 (FIG. 1C) of the base structure 106 exposed by the remainder of the opening 108.

The conductive pad 112 may be formed of and include conductive material. A material composition of the conductive pad 112 may be different than a material composition of the base structure 106. By way of non-limiting example, the conductive pad 112 may be formed of and include one or more of elemental metal and metal nitride. In some embodiments, the conductive pad 112 is formed of and includes at least one titanium-containing material, such as one or more of elemental titanium (Ti) and titanium nitride (TiNy). The conductive pad 112 may be substantially homogeneous or may be heterogeneous.

A vertical height (e.g., vertical thickness) of the conductive pad 112 may at least partially depend on the dimensions of the remainder of the opening 108 following the processing stage previously described with reference to FIG. 1C, and on dimensions of additional materials and structures to be formed within the opening 108 after the formation of the conductive pad 112. By way of non-limiting example, a vertical height of the conductive pad 112 may be within a range of from about 2 nm to about 200 nm, such as from about 2 nm to about 100 nm, from about 2 nm to about 50 nm.

Referring next to FIG. 1E, optionally, metal nitride liner material 114 may be formed (e.g., conformally formed) on or over exposed surfaces of the microelectronic device structure 100 inside and outside of the opening 108. The metal nitride liner material 114 may partially (e.g., less than completely) fill a remaining (e.g., unfilled) portion of the opening 108. For example, the metal nitride liner material 114 may be formed on or over an exposed surface (e.g., upper surface) of the conductive pad 112 within the opening 108, and on or over exposed surfaces of the dielectric liner material 110 inside and outside the opening 108. In additional embodiments, the metal nitride liner material 114 is not formed (e.g., is omitted).

The metal nitride liner material 114, if formed, may be formed of and include at least one metal nitride. By way of non-limiting example, the metal nitride liner material 114 may be formed of and include one or more of tantalum nitride, tungsten nitride, and titanium nitride. In some embodiments, the metal nitride liner material 114 is formed of and includes TiN_{y}. The metal nitride liner material 114 may be substantially homogeneous or may be heterogeneous. A thickness of the metal nitride liner material 114 (if any) may be within a range of from about 3 nm to about 25 nm, such as from about 3 nm to about 20 nm, from about 3 nm to about 15 nm.

Referring next to FIG. 1F, a metal silicide liner material 116 may be formed (e.g., conformally formed) on or over exposed surfaces inside and outside of the opening 108. The metal silicide liner material 116 may partially (e.g., less than completely) fill a remaining portion of the opening 108. If the metal nitride liner material 114 is formed, the metal silicide liner material 116 may substantially cover exposed surfaces of the metal nitride liner material 114 inside and outside of the opening 108. If the metal nitride liner material 114 is not formed, metal silicide liner material 116 may be formed on or over an exposed surface (e.g., upper surface) of the conductive pad 112 within the opening 108, and on or over exposed surfaces of the dielectric liner material 110 inside and outside the opening 108.

The metal silicide liner material 116 may be formed of and include at least one metal silicide. The metal of the metal silicide may be selected based on a desired material composition of conductive material to subsequently be formed with the opening 108. As described in further detail below, the metal silicide liner material 116 may be employed as a nucleation material (e.g., a seed material) to control grain sizes of the conductive material. By way of non-limiting example, the metal silicide liner material 116 may be formed of and include one or more tantalum silicide (TaSiₓ), tungsten silicide (WSiₓ), titanium silicide (TiSiₓ), cobalt silicide (CoSiₓ), manganese silicide (MnSiₓ), nickel silicide (NiSiₓ), and copper silicide (CuSiₓ). In some embodiments, the metal silicide liner material 116 is formed of and includes WSiₓ. In some embodiments, the metal silicide liner material 116 is formed of and includes a stoichiometric compound, such as WSi₂. In additional embodiments, the metal silicide liner material 116 is formed of and includes a non-stoichiometric compound. The metal silicide liner material 116 may be substantially homogeneous or may be heterogeneous.

As previously mentioned, the metal silicide liner material 116 may be employed as nucleation material (e.g., a seed material, template material) for the subsequent formation of conductive material (e.g., conductive fill material) thereon. Grain sizes of the subsequently formed conductive material are influenced by the material composition of the metal silicide liner material 116. For example, depending on a material composition (e.g., atomic percentage of Si) of the metal silicide liner material 116, the subsequently formed conductive material may have grain sizes that are about five (5) times (5×) to about seven (7) times (7×) larger as compared to conventional configurations wherein the metal silicide liner material 116 is not formed.

An amount of silicon within the metal silicide liner material 116 may be selected based, at least in part, on desired grain sizes for the subsequently formed conductive material. An atomic percentage of silicon in the metal silicide liner material 116 may be within a range of from about 1 atomic percent (atomic %) to about 50 atomic %, such as from about 1 atomic % to about 40 atomic %, from about 1 atomic % to about 35 atomic %, from about 1 atomic % to about 30 atomic %, or from about 1 atomic % to about 20 atomic %. In some embodiments, the atomic percentage of silicon in the metal silicide liner material 116 is within a range of from about 1 atomic % to about 20 atomic %. In addition, an average grain size of metal silicide particles within the metal silicide liner material 116 may also be selected to facilitate desirable grain sizes for the subsequently formed conductive material. For example, the average grain size of the metal silicide liner material 116 may be within a range of from about 0.2 nanometer (nm) to about 2 nm, such as from about 0.2 nm to about 0.5 nm, from about 0.2 nm to about 1 nm, from about 0.2 nm to about 1.5 nm, from about 0.5 nm to about 1 nm, from about 0.5 nm to about 1.2 nm, from about 0.5 to about 2 nm, from about 1 nm to about 1.5 nm, from about 1 nm to about 2 nm, from about 1.2 nm to about 2 nm, or from about 1.5 nm to about 2 nm. The metal silicide liner material 116 may have a Root Mean Square (RMS) surface roughness within a range of from about 0.3 nm to about 2 nm.

Optionally, the metal silicide liner material 116 may include one or more additives (e.g., dopants), such as one or more of boron, germanium, arsenic, antimony, and tellurium. If included in the metal silicide liner material 116, the one or more dopants may be included partially in place of or in combination with silicon of the metal silicide liner material 116.

A density of the metal silicide liner material 116 may be within a range of from about 13.5 grams per cubic centimeter (g/cm³) to about 17.9 g/cm³.

A thickness of the metal silicide liner material 116 may at least partially depend on the dimensions (e.g., horizontal dimension, vertical dimensions) of the opening 108 and on dimensions of additional materials and structures formed within and/or to be formed within the opening 108. By way of non-limiting example, the thickness of the metal silicide liner material 116 may be within a range of from about two (2) nm to about 10 nm, such as from about 2 nm to about 8 nm, or from about 2 nm to about 5 nm. In some embodiments, the metal silicide liner material 116 is formed to exhibit a thickness within a range of from about 2 nm to about 4 nm.

The metal silicide liner material 116 may be formed using at least one conformal deposition process, such as one or more of an ALD process and a conformal CVD process. In addition, metal silicide material of the metal silicide liner material 116 may, optionally, be doped with one or more dopants using one or more of a material implantation process and a conventional material diffusion process.

Referring next to FIG. 1G, a conductive fill material 118 may be formed (e.g., non-conformally deposited, conformally deposited) inside and outside of a remaining (e.g., unfilled) portion of the openings 108 (FIG. 1F). The conductive fill material 118 may substantially fill the remaining portions of the opening 108 (FIG. 1F), and may also substantially cover exposed surfaces of the microelectronic device structure 100 outside of the boundaries (e.g., horizontal boundaries, vertical boundaries) of the remaining portion of the opening 108.

The conductive fill material 118 may be formed of and include at least one conductive material, such as one or more of a metal (e.g., W, Ti, Mo, Nb, V, Hf, Ta, Cr, Zr, Fe, Ru, Os, Co, Rh, Ir, Ni, Pd, Pt, Cu, Ag, Au, Al), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, a stainless steel), and a conductive metal-containing material (e.g., a conductive metal nitride, a conductive metal silicide, a conductive metal carbide, a conductive metal oxide). For example, the conductive fill material 118 is formed of and includes metallic material including the same metal as metal included within the metal silicide liner material 116. In some embodiments, the conductive fill material 118 is formed of and includes tungsten (W).

An average grain size of the conductive fill material 118 may be controlled by the configuration (e.g., material composition, silicon concentration, grain sizes) of the metal silicide liner material 116. The average grain size of the conductive fill material 118 may be greater than or equal to about 200 nm, such as within a range of from about 200 nm to about 800 nm, from about 200 nm to about 700 nm, from about 250 nm to about 700 nm, from about 250 nm to about 650 nm, from about 300 nm to about 650 nm, from about 350 nm to about 650 nm, from about 400 nm to about 650 nm, from about 450 nm to about 650 nm, from about 500 nm to about 650 nm, from about 500 nm to about 600 nm, or from about 550 nm to about 600 nm. In some embodiments, the mean grain size of the conductive fill material 118 is within a range of from about 250 nm to about 650 nm. Grains of the conductive fill material 118 may individually have a grain size within a range of from about 100 nm to about 1000 nm, such as from about 100 to about 800 nm, from about 200 to about 700 nm, or from about 250 nm to about 650 nm. In some embodiments the conductive fill material 118 is formed through one of a CVD process and a PVD process permitting the average grain size of the conductive fill material 118 to be controlled to be within the range of from about 200 nm to about 800 nm using the metal silicide liner material 116 as a template with a Si concentration of the metal silicide liner material 116 within a range of from about 5 atomic percent (atom %) Si to about 35 atomic % Si. The conductive fill material 118 may have relatively lower resistivity than may otherwise be achieved if the conductive fill material 118 was formed without previously forming metal silicide liner material 116.

The conductive fill material 118 may be configured to have desirable tensile stress. The tensile stress exhibited by the conductive fill material 118 may be controlled by the configuration (e.g., material composition, silicon concentration, grain sizes) of the metal silicide liner material 116. The conductive fill material 118 may have a tensile stress greater than about 1000 MPa. For example, the conductive fill material 118 may have a tensile stress within a range of from about 1000 MPa to about 1500 MPa, from about 1000 MPa to about 2000 MPa, from about 1500 MPa to about 1800 MPa, from about 1500 MPa to about 2000 MPa, from about 1500 MPa to about 2600 MPa, from about 1800 MPa to about 2000 MPa, from about 1800 MPa to about 2200 MPa, from about 1800 MPa to about 2600 MPa, from about 2000 MPa to about 2200 MPa, or from about 2000 MPa to about 2600 MPa. The conductive fill material 118, as influenced by the metal silicide liner material 116 thereunder serving as a template to achieve the grain sizes and associated properties of the conductive fill material 118, may have greater tensile stress in comparison to conductive material formed in the absence of the metal silicide liner material 116.

The amount (e.g., atomic %) of silicon of the metal silicide liner material 116 may also influence proportions of specific crystal orientations within the conductive fill material 118 (e.g., [110], [001], and orientations). Modifying an atomic percentage of silicone in the metal silicide liner material 116 may effectuate a change in the proportion of specific crystal orientations of the conductive fill material 118. By way of non-limiting example, in an embodiment where the conductive fill material 118 is tungsten, a crystal orientation of [110] or [001] of the conductive fill material 118 can be increased by a range of from about 20% to about 30% with a change in the atomic percentage of silicon in the metal silicide liner material 116 of from about 10 atomic % Si to about 30 atomic % Si.

Referring next to FIG. 1H, portions of the dielectric liner material 110, the metal nitride liner material 114 (if any), the metal silicide liner material 116, and the conductive fill material 118 outside of boundaries (e.g., horizontal boundaries, vertical boundaries) of the opening 108 (FIG. 1B) may be removed from a conductive contact structure 119 and a dielectric liner structure 111 horizontally surrounding the conductive contact structure 119. The conductive contact structure 119 may include remaining (e.g., unremoved) portions of the metal nitride liner material 114 (if present), the metal silicide liner material 116, and the conductive fill material 118. The conductive contact structure 119 may also include the conductive pad 112. The dielectric liner structure 111 may include remaining (e.g., unremoved) portions of the dielectric liner material 110. In some embodiments, the microelectronic device structure 100 is subjected to at least one CMP process to form the conductive contact structure 119 and a dielectric liner structure 111. As shown in FIG. 1H, following the material removal process, an upper surface of the conductive contact structure 119 may be substantially coplanar with upper surfaces of the dielectric liner structure 111 and the preliminary stack structure 101.

Referring next to FIG. 1I, the preliminary stack structure 101 (FIG. 1H) of microelectronic device structure 100 may be subjected to so-called replacement gate processing to form a stack structure 123. The stack structure 123 may include a vertically alternating (e.g., in a Z-direction) sequence of the insulative material 104 and conductive material 120 arranged in tiers 121. The tiers 121 of the stack structure 123 may individually include a level of the conductive material 120 vertically neighboring (e.g., directly vertically adjacent) a level of the insulative material 104. The conductive material 120 of the stack structure 123 may be formed (e.g., deposited) in place of the sacrificial material 102 (FIG. 1H) of the tiers 103 of the preliminary stack structure 101 (FIG. 1H), as described in further detail below. In some embodiments, the conductive material 120 is formed of and includes W. Optionally, at least one liner material (e.g., at least one insulative liner material, at least one conductive liner materials) may be formed around the conductive material 120. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive material 120. In some embodiments, the liner material comprises titanium nitride (TiNₓ, such as TiN). In further embodiments, the liner material further includes aluminum oxide (AlOₓ, such as Al₂O₃). As a non-limiting example, AlOₓ (e.g., Al₂O₃) may be formed directly adjacent the insulative material 104, TiNₓ (e.g., TiN) may be formed directly adjacent the AlOₓ, and W may be formed directly adjacent the TiNₓ. For clarity and ease of understanding the description, the liner material is not illustrated in FIG. 1I, but it will be understood that the liner material may be disposed around the conductive material 120.

To form the stack structure 123, slots (e.g., trenches, openings, apertures) may be formed in the preliminary stack structure 101 (FIG. 1H). Thereafter, the microelectronic device structure 100 may be treated with at least one wet etchant formulated to selectively remove portions of the sacrificial material 102 (FIG. 1H) of the tiers 103 (FIG. 1H) of the preliminary stack structure 101 (FIG. 1H) through the slots. The wet etchant may be selected to remove the portions of the sacrificial material 102 (FIG. 1H) without substantially removing portions of the insulative material 104 of the tiers 103 (FIG. 1H) of the preliminary stack structure 101 (FIG. 1H), and without substantially removing portions of the dielectric liner structure 111. During the material removal process, the dielectric liner structure 111 may protect (e.g., mask) the conductive contact structure 119 from being removed. In some embodiments wherein the sacrificial material 102 (FIG. 1H) includes dielectric nitride material (e.g., SiN_{y}, such as Si₃N₄) and the insulative material 104 and the dielectric liner structure 111 include dielectric oxide material (e.g., SiOₓ, such as SiO₂), the sacrificial material 102 (FIG. 1H) of the tiers 103 (FIG. 1H) of the preliminary stack structure 101 (FIG. 1H) is selectively removed using a wet etchant comprising H₃PO₄. Following the selective removal of the portions of the sacrificial material 102 (FIG. 1H), the resulting recesses may be filled with conductive material to form the conductive material 120 of the stack structure 123. During the replacement gate processing, the configuration of the conductive contact structure 119 (e.g., the configuration of the conductive fill material 118 thereof, including the relatively larger grain sizes facilitated by the metal silicide liner material 116 thereof) may mitigate stresses (e.g., tensile stresses) that may otherwise result in undesirable deformations (e.g., bending, warping) and/or undesirable damage to the conductive contact structure 119, the slots, and/or the stack structure 123. Thereafter, the slots may be filled (e.g., substantially filled) with at least one dielectric material (e.g., at least one dielectric oxide material, such as SiOₓ; at least one dielectric nitride material, such as SiN_{y}) to form slot structures. In some embodiments, the slot structures are formed of and include SiO₂. The slot structures may individually be formed to be substantially homogeneous, or may individually be formed to be heterogeneous.

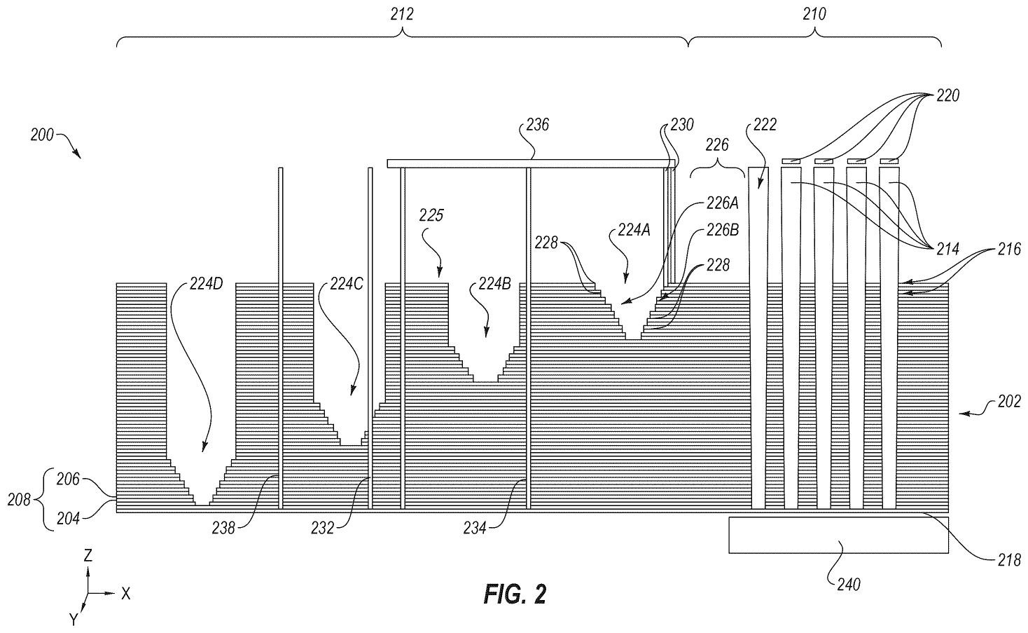

Microelectronic device structures (e.g., the microelectronic device structure 100 following the processing stage previously described with reference to FIG. 1I) of the disclosure may be included in microelectronic devices of the disclosure. For example, FIG. 2 is a simplified, partial vertical cross-sectional view of a microelectronic device 200, in accordance with embodiments of the disclosure. As shown in FIG. 2, the microelectronic device 200 includes a stack structure 202 overlying a source structure 218 and including a vertically alternating (e.g., in the Z-direction) sequence of insulative material 204 and conductive material 206 arranged in tiers 208. The stack structure 202, including the tiers 208 thereof, may be substantially similar to the stack structure 123 (FIG. 1I) of the microelectronic device structure 100 (FIG. 1I).

The stack structure 202 may be divided into a memory array region 210 and a staircase region 212 horizontally neighboring (e.g., in the X-direction) the memory array region 210. As described in further detail below, the microelectronic device 200 includes additional components (e.g., features, structures, devices) within boundaries of the memory array region 210 and the staircase region 212 of the stack structure 202.

As shown in FIG. 2, within a horizontal area of the memory array region 210 of the stack structure 202, the microelectronic device 200 may include cell pillar structures 214 vertically extending through the stack structure 202. Intersections of the cell pillar structures 214 and the conductive material 206 of the tiers 208 of the stack structure 202 form strings of memory cells 216 vertically extending through the stack structure 202. For each string of memory cells 216, the memory cells 216 thereof may be coupled in series with one another. The conductive material 206 of some of the tiers 208 of the stack structure 202 may serve as access line structures (e.g., word line structures) for the strings of memory cells 216. In some embodiments, the memory cells 216 formed at the intersections of the conductive material 206 of some of the tiers 208 and the cell pillar structures 214 comprise so-called “MONOS” (metal-oxide-nitride-oxide-semiconductor) memory cells. In additional embodiments, the memory cells 216 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 216 comprise so-called “floating gate” memory cells including floating gates (e.g., metallic floating gates) as charge storage structures. The floating gates may horizontally intervene between central structures of the cell pillar structures 214 and the conductive material 206 of the different tiers 208 of the stack structure 202. In addition, digit line structures 220 may vertically overlie and be coupled to the cell pillar structures 214 (and, hence, the strings of memory cells 216); and the source structure 218 may vertically underlie and be coupled to the cell pillar structures 214 (and, hence, the strings of memory cells 216).

Within the horizontal area of the memory array region 210 of the stack structure 202, the microelectronic device 200 may further include first contact structures 222 (e.g., through-array-via (TAV) contact structures) horizontally offset from the cell pillar structures 214 and vertically extending completely through stack structure 202. The first contact structures 222 may, for example, vertically extend to or into the source structure 218. In some embodiments, one or more of the first contact structures 222 respectively have a configuration substantially similar to that of the conductive contact structure 119 (including the configurations of the metal nitride liner material 114, the metal silicide liner material 116, the conductive fill material 118, and the conductive pad 112) previously described with reference to FIG. 1I. In such embodiments, the one or more of the first contact structures 222 may be formed through a process substantially similar to that previously described herein with reference to FIGS. 1A through 1I. The source structure 218 may, for example, correspond to the base structure 106 (FIG. 1I). Dielectric liner structures corresponding to the dielectric liner structure 111 (FIG. 1I) may horizontally surround and vertically extend across the one or more first contact structures 222.

Still referring to FIG. 2, the staircase region 212 of the stack structure 202 includes stadium structures 224 horizontally alternating (e.g., in the X-direction) with crest regions 225 (which may also be referred to as “elevated regions” or “plateau regions”). The stadium structures 224 may respectively include staircase structures 226 individually, including steps 228 defined by edges (e.g., horizontal ends) of some of the tiers 208 of the stack structure 202. An individual stadium structure 224 may, for example, include a first staircase structure 226A having negative slope, and a second staircase structure 226B opposing the first staircase structure 226A and having positive slope. At least some of the stadium structures 224 with the staircase region 212 may be located at different vertical positions within the stack structure 202 than one another. As a non-limiting example, the stadium structures 224 may include a first stadium structure 224A, a second stadium structure 224B at a relatively lower vertical position (e.g., in the Z-direction) within the stack structure 202 than the first stadium structure 224A, a third stadium structure 224C at a relatively lower vertical position within the stack structure 202 than the second stadium structure 224B, and a fourth stadium structure 224D at a relatively lower vertical position within the stack structure 202 than the third stadium structure 224C.

Within the horizontal area of the staircase region 212 of the stack structure 202, the microelectronic device 200 may further include second contact structures 230, third contact structures 232, fourth contact structures 234, and fifth contact structures 238. The second contact structures 230 and the third contact structures 232 may be positioned within horizontal areas of the stadium structures 224. The second contact structures 230 may respectively vertically extend to and terminate at (e.g., land on) one of the steps 228 of one of the staircase structures 226 of an individual stadium structure 224; and the third contact structures 232 may respectively horizontally overlap one of the stadium structures 224, and may vertically extend completely through the stack structure 202. The second contact structures 230 may be employed to couple the conductive material 206 of the tiers 208 of the stack structure 202 to additional components (e.g., control circuitry) of the microelectronic device 200. At least some of the third contact structures 232 may be employed as support structures for the stack structure 202 (e.g., to impede tier collapse during replacement gate processing). In addition, the fourth contact structures 234 and the fifth contact structures 238 may be positioned within horizontal areas of the crest regions 225. The fourth contact structures 234 and the fifth contact structures 238 may respectively vertically extend completely through the stack structure 202. The fourth contact structures 234 may be considered “active” contact structures for the microelectronic device 200, with at least some of the fourth contact structures 234 coupled to at least some of the second contact structures 230 by way of conductive routing structures 236 vertically overlying the stack structure 202. At least some of the fifth contact structures 238 may be employed as support structures for the stack structure 202.

In some embodiments, one or more of the second contact structures 230, one or more of the third contact structures 232, one or more of the fourth contact structures 234, and/or one or more fifth contact structures 238, respectively, have a configuration substantially similar to that of the conductive contact structure 119 (including the configurations of the metal nitride liner material 114, the metal silicide liner material 116, the conductive fill material 118, and the conductive pad 112) previously described with reference to FIG. 1I. In some such embodiments, the one or more of the second contact structures 230, the one or more of the third contact structures 232, the one or more of the fourth contact structures 234, and/or the one or more fifth contact structures 238 may be formed through a process substantially similar to that previously described herein with reference to FIGS. 1A through 1I. In additional embodiments, the formation process is, in part, different than that previously described herein with reference to FIGS. 1A through 1I. For example, for the second contact structures 230, an opening (e.g., corresponding the opening 108 (FIG. 1B)) may be formed in at least one additional insulative material at least partially overlying the stack structure 202 (e.g., before or after replacement gate processing) rather than in a preliminary stack structure to become the stack structure 202. Dielectric liner structures corresponding to the dielectric liner structure 111 (FIG. 1I) may horizontally surround and vertically extend across the one or more of the second contact structures 230, the one or more of the third contact structures 232, the one or more of the fourth contact structures 234, and/or the one or more fifth contact structures 238.

Still referring to FIG. 2, the microelectronic device 200 may also include a control circuitry structure 240 positioned vertically below the cell pillar structures 214 (and, hence, the strings of memory cells 216). The control circuitry structure 240 may include at least one control logic region including control logic devices configured to control various operations of other features (e.g., the strings of memory cells 216) of the microelectronic device 200. As a non-limiting example, the control logic region of the control circuitry structure 240 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the control circuitry structure 240 may be coupled to the source structure 218, the conductive material 206 of the tiers 208 of the stack structure 202, and the digit line structures 220. In some embodiments, the control logic region of the control circuitry structure 240 includes CMOS (complementary metal-oxide-semiconductor) circuitry. In such embodiments, the control logic region of the control circuitry structure 240 may be characterized as having a “CMOS under Array” (“CuA”) configuration.

Thus, in accordance with embodiments of the disclosure, a microelectronic device includes a conductive structure and a conductive contact structure on the conductive structure. The conductive contact structure on the conductive structure includes a conductive pad structure, a metal silicide material over the conductive pad structure, and a conductive fill material surrounded by the metal silicide material. The metal silicide material physically contacts and substantially covers sidewalls and a bottom surface of the conductive fill material.

Furthermore, in accordance with embodiment of the disclosure, a method of forming a microelectronic device includes forming an opening vertically extending through a stack structure to a conductive structure thereunder. The stack structure comprising tiers respectively comprising sacrificial material and insulative material vertically neighboring the sacrificial material. A dielectric oxide material is formed to substantially cover sidewalls of the stack structure exposed within the opening. A conductive pad structure is formed within the opening and on an upper surface of the conductive structure. A metal silicide material is conformally formed within the opening after forming the conductive pad structure. A conductive fill material is formed within the opening and on the metal silicide material, the conductive fill material comprising a metal element also included within the metal silicide material.

Moreover, in accordance with embodiment of the disclosure, a memory device comprises a stack structure, strings of memory cells, and conductive contact structures. The stack structure includes vertically alternating conductive material and insulative material arranged in tiers. The strings of memory cells vertically extend through the stack structure. The conductive contact structures are horizontally offset from the strings of memory cells and vertically extending through the stack structure. The conductive contact structures respectively include a central tungsten structure, and a tungsten silicide liner structure on and substantially covering side surfaces and a bottom surface of the central tungsten structure. The tungsten silicide liner includes from about 1 atomic percent silicon to about 35 atomic percent silicon.

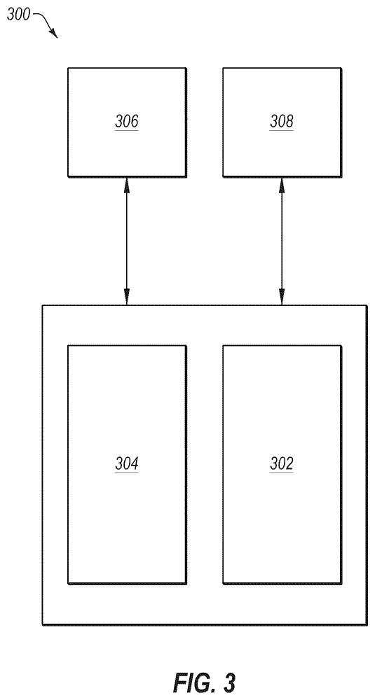

Microelectronic device structures (e.g., the microelectronic device structure 100 (FIG. 1I)) and microelectronic devices (e.g., the microelectronic device 200 (FIG. 2)) in accordance with embodiments of the disclosure may be used in embodiments of electronic systems of the disclosure. For example, FIG. 3 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 300 includes at least one memory device 302. The memory device 302 may comprise, for example, an embodiment of one or more of a microelectronic device structure (e.g., the microelectronic device structure 100 (FIG. 1I)) and a microelectronic device (e.g., the microelectronic device 200 (FIG. 2)) previously described herein. The electronic system 300 may further include at least one electronic signal processor device 304 (often referred to as a “microprocessor”). The electronic signal processor device 304 may, optionally, include an embodiment of one or more of a microelectronic device structure (e.g., the microelectronic device structure 100 (FIG. 1I)) and a microelectronic device (e.g., the microelectronic device 200 (FIG. 2)). While the memory device 302 and the electronic signal processor device 304 are depicted as two (2) separate devices in FIG. 3, in additional embodiments, a single (e.g., only one) memory/processor device having the functionalities of the memory device 302 and the electronic signal processor device 304 is included in the electronic system 300. In such embodiments, the memory/processor device may include one or more of a microelectronic device structure (e.g., the microelectronic device structure 100 (FIG. 1I)) and a microelectronic device (e.g., the microelectronic device 200 (FIG. 2)) previously described herein. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

The structures (e.g., the microelectronic device structure 100, including the conductive contact structure 119 thereof), devices (e.g., the microelectronic device 200), and systems (e.g., the electronic system 300) of the disclosure advantageously facilitate one or more of improved performance, reliability, and durability, lower costs, increased miniaturization of components, improved pattern quality, and greater packaging density as compared to conventional structures, conventional devices, and conventional systems.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a conductive structure; and
a conductive contact structure on the conductive structure and comprising:
a conductive pad structure;
a metal silicide material over the conductive pad structure; and
a conductive fill material surrounded by the metal silicide material, the metal silicide material physically contacting and substantially covering sidewalls and a bottom surface of the conductive fill material.

2. The microelectronic device of claim 1, wherein the conductive contact structure further comprises a metal nitride material between the conductive pad structure and the metal silicide material, the metal nitride material physically contacting and substantially covering outer sidewalls and a lowermost surface of the metal silicide material.

3. The microelectronic device of claim 1, wherein:
the conductive pad structure comprises titanium;
the metal silicide material comprises tungsten silicide; and
the conductive fill material comprises elemental tungsten.

4. The microelectronic device of claim 1, wherein the metal silicide material of the conductive contact structure comprises from about 1 atomic percent silicon to about 35 atomic percent silicon.

5. The microelectronic device of claim 1, further comprising a dielectric oxide liner material surrounding the conductive contact structure, the dielectric oxide liner material physically contacting and substantially covering sidewalls of the conductive contact structure.

6. The microelectronic device of claim 1, further comprising a stack structure vertically overlaying the conductive structure and having tiers respectively comprising conductive material and insulative material vertically neighboring the conductive material, the conductive contact structure vertically extending completely through the stack structure.

7. The microelectronic device of claim 1, wherein a density of the metal silicide material is within a range of from about 13.5 g/cm³ to about 17.9 g/cm³.

8. A method of forming a microelectronic device, comprising:
forming an opening vertically extending through a stack structure to a conductive structure thereunder, the stack structure comprising tiers respectively comprising sacrificial material and insulative material vertically neighboring the sacrificial material;
forming a dielectric oxide material to substantially cover sidewalls of the stack structure exposed within the opening;
forming a conductive pad structure within the opening and on an upper surface of the conductive structure;
conformally forming a metal silicide material within the opening after forming the conductive pad structure; and
forming a conductive fill material within the opening and on the metal silicide material, the conductive fill material comprising a metal element also included within the metal silicide material.

9. The method of claim 8, wherein the method further comprising conformally forming a metal nitride material within the opening before forming the metal silicide material.

10. The method of claim 8, further comprising selecting the metal silicide material to include from about 1 atomic % silicon to about 35 atomic % silicon.

11. The method of claim 10, further comprising:
selecting the metal silicide material to comprise tungsten silicide; and
selecting the conductive fill material to comprise elemental tungsten.

12. The method of claim 8, wherein conformally forming a metal silicide material comprises forming the metal silicide material through one of atomic layer deposition and chemical vapor deposition.

13. The method of claim 8, wherein conformally forming a metal silicide material comprises forming the metal silicide material to have a thickness within a range of from about 2 nanometers (nm) to about 10 nm.

14. The method of claim 8, further comprising selecting the conductive pad structure to comprise elemental titanium.

15. The method of claim 8, wherein:
forming a dielectric oxide material comprises:
conformally forming the dielectric oxide material on the sidewalls of the stack structure and on the upper surface of the conductive structure; and
removing portions of the dielectric oxide material on the upper surface of the conductive structure; and
forming a conductive pad structure comprises forming the conductive pad structure to be substantially horizontally circumscribed by a remaining portion of the dielectric oxide material within the opening.

16. The method of claim 8, further comprising, after forming the conductive fill material, removing portions of the conductive fill material, the metal silicide material, and the dielectric oxide material outside of boundaries of the opening.

17. The method of claim 16, further comprising replacing the sacrificial material of the tiers of the stack structure with conductive material.

18. A memory device, comprising:
a stack structure including vertically alternating conductive material and insulative material arranged in tiers;
strings of memory cells vertically extending through the stack structure; and
conductive contact structures horizontally offset from the strings of memory cells and vertically extending through the stack structure, the conductive contact structures respectively comprising:
a central tungsten structure; and
a tungsten silicide liner structure on and substantially covering side surfaces and a bottom surface of the central tungsten structure, the tungsten silicide liner structure comprising from about 1 atomic percent silicon to about 35 atomic percent silicon.

19. The memory device of claim 18, wherein the conductive contact structures respectively further comprise:
a titanium nitride liner structure on and substantially covering outer side surfaces and a lowermost surface of the tungsten silicide liner structure; and
a titanium pad structure vertically underlying and in physical contact with the titanium nitride liner structure.

20. The memory device of claim 18, wherein an average grain size of the central tungsten structure is within the range of from about 200 nm to about 800 nm.
